(19) United States
(12) Patent Application Publication
(10) Pub. No.: US 2026/0206598 A1
(43) Pub. Date: Jul. 16, 2026

(54) SEMICONDUCTOR PACKAGE

(71) Applicant: ELECTRONICS AND TELECOMMUNICATIONS RESEARCH INSTITUTE, Daejeon (KR)

(72) Inventor: Hyun-cheol BAE, Daejeon (KR)

(21) Appl. No.: 19/311,050

(22) Filed: Aug. 27, 2025

(30) Foreign Application Priority Data
Jan. 14, 2025 (KR) 10-2025-0005686

(51) Int. Cl. H01L 23/552; H01L 23/00; H01L 23/29; H01L 23/495

(52) U.S. Cl. CPC H10W 42/20; H10W 70/417; H10W 70/481; H10W 72/634; H10W 72/646; H10W 72/652; H10W 72/871; H10W 72/884; H10W 72/886; H10W 74/47; H10W 90/736; H10W 90/756; H10W 90/766

(57) ABSTRACT

Provided is a semiconductor package including a semiconductor chip, a lead frame provided on a bottom surface of the semiconductor chip and extending beyond a first side of the semiconductor chip, a wire extending from a first area of a top surface of the semiconductor chip, wherein the wire is connected to the lead frame from the first side of the semiconductor chip, and a shielding structure covering a second area of the top surface of the semiconductor chip and exposing the first area. The shielding structure may include a contact unit covering the second area of the top surface of the semiconductor chip, a protruding unit connected to the lead frame from a second side of the semiconductor chip, and a connection unit connecting the contact unit and the protruding unit. The shielding structure may include tungsten (W).

### CROSS-REFERENCE TO RELATED APPLICATION(S)

This U.S. non-provisional patent application claims priority under 35 U.S.C. § 119 of Korean Patent Application No. 10-2025-0005686, filed on Jan. 14, 2025, the entire contents of which are hereby incorporated by reference.

### BACKGROUND

### 1. Field of the Invention

The present disclosure herein relates to a semiconductor package, and more particularly, to a semiconductor package capable of protecting a semiconductor element from radiation.

### 2. Description of Related Art

With the development of science and technology, a semiconductor element for aerospace is increasingly necessary for researching satellite communication and space. In case of the semiconductor element for aerospace, there is an issue that degradation in performance, which does not occur when used in the existing earth environment, appears due radiation.

In order to protect the semiconductor element from such radiation, various semiconductor packaging technologies are being proposed. By way of an example, a closed packaging technology based on ceramic and metal has been proposed.

However, this package is heavy and bulky. Accordingly, a technology is required to manufacture a miniaturized and lightweight radiation-resistant semiconductor package.

### SUMMARY

The present disclosure provides a semiconductor package capable of shielding radiation.

The technical objects of the present disclosure are not limited to the above-mentioned ones, and the other unmentioned technical objects will become apparent to those skilled in the art from the following description.

An embodiment of the inventive concept provides a semiconductor package including: a semiconductor chip; a lead frame provided on a bottom surface of the semiconductor chip and extending beyond a first side of the semiconductor chip; a wire extending from a first area of a top surface of the semiconductor chip, wherein the wire is connected to the lead frame from the first side of the semiconductor chip; and a shielding structure covering a second area of the top surface of the semiconductor chip and exposing the first area, wherein the shielding structure may include: a contact unit covering the second area of the top surface of the semiconductor chip; a protruding unit connected to the lead frame from a second side of the semiconductor chip; and a connection unit connecting the contact unit and the protruding unit. The shielding structure may include tungsten (W).

In an embodiment of the inventive concept, a semiconductor package includes: a semiconductor chip, wherein the semiconductor chip may include a gate terminal protruding from a top surface of the semiconductor chip; a lead frame provided on a bottom surface of the semiconductor chip and extending to one side of the semiconductor chip; and a shielding structure covering at least a portion of the top surface of the semiconductor chip, wherein the shielding structure may include: a contact unit covering at least a portion of the top surface of the semiconductor chip; a protruding unit connected to the lead frame; and a connection unit connecting the contact unit and the protruding unit, and bent from the contact unit. The contact unit may surround at least three of sides of the gate terminal.

In an embodiment of the inventive concept, a semiconductor package includes: a substrate including a wiring layer; a semiconductor chip disposed on a top surface of the substrate; a first lead and a second lead spaced apart from the semiconductor chip on the top surface of the substrate; and a shielding structure covering an entire top surface of the semiconductor chip, wherein each of the first lead and the second lead may extend to one side of the substrate in one direction parallel to the top surface of the substrate. The shielding structure may include a first bottom surface and a second bottom surface positioned at different vertical levels, the first bottom surface may cover the top surface of the semiconductor chip, and the second bottom surface may be connected to the top surface of the semiconductor chip. The semiconductor chip may include a semiconductor substrate and a drain terminal provided on a top surface of the semiconductor substrate, and the shielding structure may electrically connect the drain terminal and the first lead.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view for explaining a semiconductor package according to an embodiment of the inventive concept;

FIG. 2 is a cross-sectional view cut along line A-A′ of FIG. 1 in order to explain a semiconductor package according to an embodiment of the inventive concept;

FIG. 3 is a plan view for explaining a semiconductor package according to an embodiment of the inventive concept;

FIG. 4 is an enlarged view for explaining a semiconductor package according to an embodiment of the inventive concept;

FIGS. 5 and 6 are perspective views for explaining semiconductor packages according to embodiments of the inventive concept;

FIG. 7 is a cross-sectional view cut along line B-B′ of FIG. 6 in order to explain a semiconductor package according to an embodiment of the inventive concept;

FIG. 8 is a perspective view for explaining a semiconductor package according to an embodiment of the inventive concept;

FIG. 9 is a plan view for explaining a semiconductor package according to an embodiment of the inventive concept, and shows the semiconductor package of FIG. 8;

FIG. 10 is a perspective view for explaining a semiconductor package according to an embodiment of the inventive concept;

FIG. 11 is a plan view for explaining a semiconductor package according to an embodiment of the inventive concept, and shows the semiconductor package of FIG. 10; and

FIGS. 12 and 15 are perspective views for explaining semiconductor packages according to embodiments of the inventive concept.

### DETAILED DESCRIPTION

The embodiments of the inventive concept will now be described with reference to the accompanying drawings for sufficiently understating configurations and effects of the inventive concept. However, the inventive concept is not limited to the following embodiments and may be embodied in different ways, and various modifications may be made thereto. The embodiments are just given to provide complete disclosure of the inventive concept and to provide thorough understanding of the inventive concept to those skilled in the art.

The terminology used herein is for the purpose of describing embodiments and is not intended to limit the scope of the inventive concept. As used herein, the singular forms “a”, “an” and “the” are intended to include the plural forms as well, unless the context clearly indicates otherwise. It will be further understood that the terms “comprises” and/or “comprising” used herein specify the presence of stated components, operations and/or elements but do not preclude the presence or addition of one or more other components, operations and/or elements. Also, as preferred embodiments, reference numerals shown according to an order of description are not limited to the order.

Unless otherwise defined in technical and scientific terms used herein, meanings which are commonly understood by those skilled in the art to which the inventive concept pertains, and descriptions of well-known functions and configurations which may unnecessarily obscure the gist of the inventive concept in the following description and the accompanying drawings will be omitted.

Although the terms first, second, or the like may be used herein to describe various regions, films (or layers), or the like, the regions and films (or layers) are not to be limited by the terms. The terms may be used herein only to distinguish one region or film (or layer) from another region or film (or layer). Throughout the specification, like numerals refer to like elements. Unless otherwise defined, all terms used herein have the same meaning as commonly understood by one of ordinary skill in the art to which the inventive concept pertains.

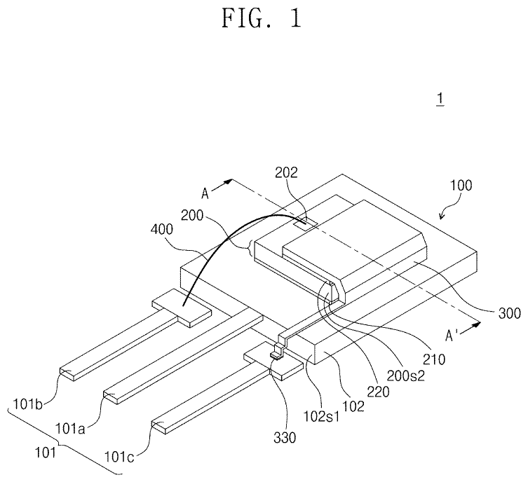

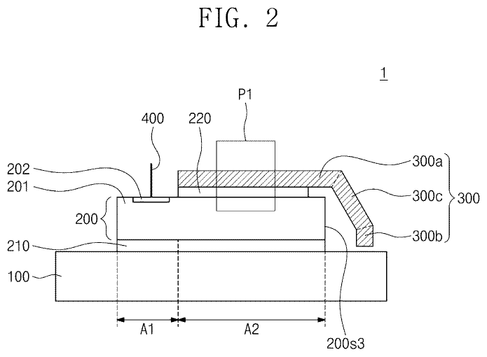

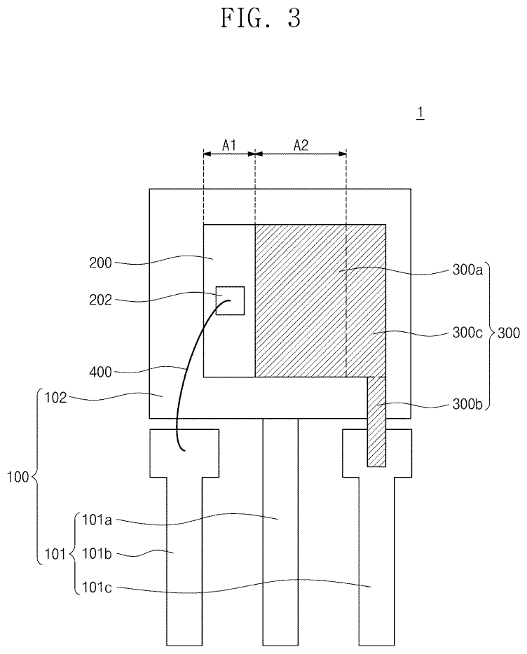

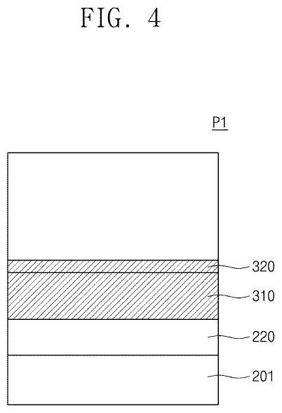

Hereinafter, a semiconductor package according to an embodiment of the inventive concept will be described with reference to the drawings. FIG. 1 is a perspective view for explaining a semiconductor package according to an embodiment of the inventive concept. FIG. 2 is a cross-sectional view cut along line A-A′ of FIG. 1 in order to explain a semiconductor package according to an embodiment of the inventive concept. FIG. 3 is a plan view for explaining a semiconductor package according to an embodiment of the inventive concept, and shows the semiconductor package of FIG. 1. FIG. 4 is an enlarged view for explaining a semiconductor package according to an embodiment of the inventive concept, which shows an enlarged portion of P1 of FIG. 2.

Referring to FIGS. 1 to 3, a semiconductor package 1 may include a lead frame 100 and a semiconductor chip 200 on the lead frame 100. The lead frame 100 may include leads 101 and a pad 102. The pad 102 may have a plate type. The pad 102 may provide a mounting surface on which the semiconductor chip 200 is mounted. In the specification, the mounting surface of the pad 102 may mean the top surface of the pad 102. In other words, the semiconductor chip 200 to be described below may be mounted on the top surface of the pad 102. The pad 102 may include conductive materials. By way of an example, the pad 102 may be composed of a metal with a relatively excellent electrical conductivity such as copper (Cu), iron-nickel (Fe—Ni), aluminum (Al), or stainless steel, or an alloy thereof.

The leads 101 may be disposed on a first side 102s1 of the pad 102. The leads 101 may extend in an outer direction of the first side 102s1 of the pad 102. The leads 101 may be horizontally spaced apart from each other at the first side 102s1 of the pad 102. Each of the leads 101 may have a linear type extending from the first side 102s1 of the pad 102 in one direction that is parallel to the top surface of the pad 102.

The leads 101 may include a first lead 101a, a second lead 101b, and a third lead 101c. The leads 101 may serve to transfer an electrical signal outside the package. Here, the first lead 101a may mean a lead through which a current input or output from a drain electrode of the semiconductor chip 200 to be described below is transferred outside. The second lead 101b may be a lead through which a current input or output from a gate electrode of the semiconductor chip 200 to be described below is transferred outside. The third lead 101c may mean a lead through which a current input or output from a source electrode of the semiconductor chip 200 to be described below is transferred outside.

The first lead 101a may contact the first side 102s1 of the pad 102. The first lead 101a may be electrically connected to the pad 102. In a plan view, the second and third leads 101b and 101c may be horizontally spaced apart from the first side 102s1 of the first pad 102. In a plan view, one ends close to the first side 102s1 of the pad 102 among both ends of the second and third leads 101b and 101c may have wider widths than the other ends.

The leads 101 may include a conductive material. By way of an example, the leads 101 may be composed of a metal with a relatively excellent electrical conductivity such as copper (Cu), iron-nickel (Fe—Ni), aluminum (Al), or stainless steel, or an alloy thereof. A material composing the leads 101 may be the same as a material composing the pad 102. However, the inventive concept is not limited thereto. A material composing the pad 102 may be different from a material composing the leads 101.

In FIG. 1, it is shown that the leads 101 are provided only at one side of the pad 102, but the inventive concept is not limited thereto. The leads 101 may protrude from two or more sides among the sides of the pad 102. By way of an example, the leads 101 may protrude in outer directions of the left and right sides of the pad 102. In addition, it is shown in FIG. 1 that some leads 101b and 101c among the leads 101 are spaced apart from the first side 102s1 of the pad 102, and the remaining lead 101a contacts the first side 102s1 of the pad 102, but the inventive concept is not limited thereto. All the leads 101 may be horizontally spaced apart from the sides of the pad 102. In addition, the number of leads 101 may vary, as necessary. Hereinbelow, description will be provided based on the embodiment of FIG. 1.

The semiconductor chip 200 may be provided on the mounting surface of the pad 102. The lead frame 100 may extend beyond a second side 200s2 of the semiconductor chip 200 from the bottom surface of the semiconductor chip 200. Here, the second side 200s2 of the semiconductor chip 200 may mean a side that is most adjacent to the first side 102s1 of the pad 102 among the sides of the semiconductor chip 200. The semiconductor chip 200 may be attached onto the pad 102 through a first adhesive layer 210. The first adhesive layer 210 may be intervened between the semiconductor chip 200 and the mounting surface of the pad 102. The first adhesive layer 210 may fill at least a portion between the bottom surface of the semiconductor chip 200 and the mounting surface of the pad 102. The first adhesive layer 210 may include a conductive material. The first adhesive layer 210 may include a solder material. By way of an example, the first adhesive layer 210 may include a lead-tin-based or indium-tin-based solder. Alternatively, the first adhesive layer 210 may include a conductive polymer adhesive. For example, the first adhesive layer 210 may include a conductive epoxy adhesive.

The semiconductor chip 200 may include vertical or horizontal elements. In the specification, the vertical element may mean a semiconductor element in which a current flows vertically. The vertical element may include at least one input unit at one side of the vertical element and an output unit at the other side. In the specification, the horizontal element may mean semiconductor elements in which a current flows horizontally. The horizontal element may include at least one input unit at one side and an output unit at the other side of the horizontal element. The type of the semiconductor chip 200 mounted on the lead frame 100 may not be limited. However, for convenience of description below, the semiconductor chip 200 is assumed to be a vertical power transistor.

The semiconductor chip 200 may include a semiconductor substrate 201. The semiconductor substrate 201 may include a semiconductor material. By way of an example, the semiconductor substrate 201 may include silicon (Si). Although not shown, the semiconductor chip 200 may include a source electrode, a drain electrode, a gate electrode, and a channel layer provided on the semiconductor substrate 201. The channel layer may serve as a passage through which electrons move. The electrons may move from the source electrode to the drain electrode through the channel layer. Furthermore, although not shown, the semiconductor chip 200 may include a gate insulation layer. The gate insulation layer may serve to insulate the gate electrode from the channel layer. The gate insulation layer may include an insulation material. By way of an example, the gate insulation layer may be composed of a material containing silicon. More specifically, the gate insulation layer may include at least one of silicon oxide (SiO₂), silicon nitride, silicon oxide nitride, or silicon nitride oxide.

A source terminal (not shown), a drain terminal (not shown), and a gate terminal 202 may be disposed on the top surface or bottom surface of the semiconductor substrate 201. The terminal in the specification may mean a portion to which an electrode through which a current is input or output. The source terminal and the drain terminal may be disposed on surfaces facing to each other on the semiconductor chip 200. By way of an example, the source terminal may be provided on the top surface of the semiconductor chip 200. The source terminal may protrude from the top surface of the semiconductor chip 200. The drain terminal may be disposed on the bottom surface of the semiconductor chip 200. The drain terminal may protrude from the bottom surface of the semiconductor chip 200. The drain terminal may be electrically connected to the first lead 101a from the bottom surface of the semiconductor chip 200 through the first adhesive layer 201 and the pad 102.

The gate terminal 202 may be provided on the same plane as the source terminal. The gate terminal may be provided on the top surface of the semiconductor chip 200. The gate terminal may protrude from the top surface of the semiconductor chip 200. However, the inventive concept is not limited thereto, and the source terminal, the drain terminal, and the gate terminal 202 may be exposed to the top surface of the semiconductor chip 200. In a plan view, the gate terminal 200 and the source terminal may be spaced apart horizontally.

The top surface of the semiconductor chip 200 may include a first area A1 and a second area A2. In a plan view, the first area A1 may be spaced apart from the second area A2 horizontally. The first area A1 of the semiconductor chip 200 may include an area in which the gate terminal 202 protrudes from the top surface of the semiconductor chip 200. A whole portion, which includes the area in which the gate terminal 202 protrudes, of the top surface of the semiconductor chip 200 may be defined as the first area A1. The second area A2 may include an area in which the source terminal protrudes from the top surface of the semiconductor chip 200. The second area A2 may mean the remaining area, which excludes the first area A1, of the top surface of the semiconductor chip 200. The planar area of the first area A1 may be narrower than that of the second area A2.

In the semiconductor chip 200, a wire 400 extending from the first area A1 of the semiconductor chip 200 may be provided. The wire 400 may be connected to the lead frame 100 from the second side 200s2 of the semiconductor chip 200. More specifically, the wire 400 may extend from the gate terminal 202 to the second lead 101b. One end of the wire 400 may contact the gate terminal 202. The other end of the wire 400 may contact the second lead 101b. The wire 200 may electrically connect the gate terminal 202 of the semiconductor chip 200 to the lead frame 100.

A shielding structure 300 may be provided on the top surface of the semiconductor chip 200. The shielding structure 300 may cover a portion of the top surface of the semiconductor chip 200. The shielding structure 300 may cover the entire second area A2 of the semiconductor chip 200. The shielding structure 300 may expose the first area A1 of the semiconductor chip 200. The shielding structure 300 may connect the lead frame 100 and the second area A2 of the semiconductor chip 200. The shielding structure 300 may electrically connect the source terminal of the semiconductor chip 200 to the third lead 101c of the lead frame 100. The shielding structure 300 may be spaced apart from the gate terminal 202 of the semiconductor chip 200.

The shielding structure 300 may include a contact unit 300a covering the top surface of the semiconductor chip 200, a protruding unit 300b connected to the lead frame 100, and a connection unit 300c connecting the contact unit 300a and the protruding unit 300b. The shielding structure 300 may be connected to the protruding unit 300b through the connection unit 300c that extends from the contact unit 300a. The shielding structure 300 may have a clip type. The shielding structure 300 may have a step structure or a zigzag structure. Hereinafter, each structure of the contact unit 300a, the protruding unit 300b, and the connection unit 300c of the shielding structure 300 will be described in detail.

The contact unit 300a may cover the source terminal of the semiconductor chip 200. The contact unit 300a may vertically overlap the second area A2 of the semiconductor chip 200. On the second area A2, the contact unit 300a may cover the top surface of the semiconductor chip 300. The contact unit 300a may be horizontally spaced apart from the gate terminal 202 of the semiconductor chip 200. The contact unit 300a may not vertically overlap the gate terminal 202 of the semiconductor chip 200. A planar shape of the contact unit 300a may be rectangular.

The protruding unit 300b may protrude from a third side 200s3 of the semiconductor chip 200. The third side 200s3 may mean a side adjacent to the protruding unit 300b and the connection unit 300c of the shielding structure 300 between two sides adjacent to the second side 200s2 of the semiconductor chip 200. The protruding unit 300b may extend from the third side 200s3 of the semiconductor chip 200 to be connected to the third lead 101c along a direction to which the leads 101 extend. The protruding unit 300b may have a linear shape in a plan view. The bottom surface of the protruding unit 300b may face the top surface of the lead frame 100. More specifically, a portion of the bottom surface of the protruding unit 300b may face the mounting surface of the pad 102. The portion of the bottom surface of the protruding unit 300b may be vertically spaced apart from the mounting surface of the pad 102. The remaining portion of the bottom surface of the protruding unit 300b may face the top surface of the third lead 101c. As necessary, the protruding unit 300b may have at least one step. By way of an example, the protruding unit 300b may have the step in an area adjacent to the third lead 101c. Due to the step, the protruding unit 300b may be spaced apart from the mounting surface of the pad 102 and be connected to the top surface of the third lead 101c.

The level of the bottom surface of the protruding unit 300b may be lower than that of the bottom surface of the contact unit 300a. In a plan view, the protruding unit 300b may be horizontally spaced apart from the semiconductor chip 200. The level of the bottom surface of the protruding unit 300b may be lower than that of the top surface of the semiconductor chip 200. In other words, the shielding structure 300 may include a first bottom surface and a second bottom surface. The first bottom surface may mean the bottom surface of the contact unit 300a. The second bottom surface may mean the bottom surface of the protruding unit 300b. The level of the first bottom surface may be higher than that of the second bottom surface. The first bottom surface may cover the top surface of the semiconductor chip 200. At least a portion of the second bottom surface may be connected to the lead frame 100.

The shielding structure 300 may include the connection unit 300c connecting the contact unit 300a to the protruding unit 300b. The connection unit 300c may extend from one side of the contact unit 300a. The connection unit 300c may have the shape bent from the top surface of the contact unit 300a. One end of the connection unit 300c may be connected to the one side of the contact unit 300a, and the other end may be connected to the top surface of the protruding unit 300b. The connection unit 300c may have the shape bent from the top surface of the protruding unit 300b. The connection unit 300c may be spaced apart from the third side 200s3 of the semiconductor chip 200. The bottom surface of the contact unit 300a forms an obtuse angle with an inner surface of the connection unit 300c. The inner surface of the connection unit 300c may be spaced apart from the third side 200s3 of the semiconductor chip 200. Here, the inner surface of the connection unit 300c may mean a side that is most adjacent to the third side 200s3 of the semiconductor chip 200 among the sides of the connection unit 300c.

The contact unit 300a may be attached onto the semiconductor chip 200 through a second adhesive layer 220. The second adhesive layer 220 may be intervened between the semiconductor chip 200 and the bottom surface of the contact unit 300a. In the second area A2, the second adhesive layer 220 may fill at least a portion between the top surface of the semiconductor chip 200 and the bottom surface of the contact unit 300a. The second adhesive layer 220 may include a conductive material. The second adhesive layer 220 may include a solder material. By way of an example, the second adhesive layer 220 may include a lead-tin-based or indium-tin-based solder. However, the inventive concept is not limited thereto, and the second adhesive layer 220 may include a conductive polymer adhesive. For example, the second adhesive layer 220 may include a conductive epoxy adhesive. A material composing the second adhesive layer 220 may be the same as a material composing the first adhesive layer 210, but the inventive concept is not limited thereto.

A third adhesive layer 330 may be provided between the protruding unit 300b and the third lead 101c. The protruding unit 300b may be attached to the third lead 101c through the third adhesive layer 330. The third adhesive layer 330 may electrically connect the protruding unit 300b to the third lead 101c. The third adhesive layer 330 may include a conductive material. The third adhesive layer 330 may include a solder material. By way of an example, the third adhesive layer 330 may include a lead-tin-based or indium-tin-based solder. However, the inventive concept is not limited thereto, and the third adhesive layer 330 may include a conductive polymer adhesive. For example, the third adhesive layer 330 may include a conductive epoxy adhesive.

The shielding structure 300 may include a conductive material. By way of an example, the contact unit 300a, the protruding unit 300b, and the connection unit 300c of the shielding structure 300 may include a metal. Referring to FIG. 4, the contact unit 300a of the shielding structure 300 may include a first metal layer 310 and a second metal layer 320 laminated along a direction vertical to the top surface of the semiconductor chip 200. By way of an example, the second metal layer 320 may be laminated on the top surface of the first metal layer 310. The first metal layer 310 may include copper (Cu). The second metal layer 320 may include tungsten (W). However, the inventive concept is not limited thereto, and the second metal layer 320 may include a material for shielding radiation. By way of an example, the second metal layer 320 may include lead (Pb), bismuth (Bi), gold (Au), silver (Ag), or the like.

In FIG. 4, it is shown that the contact unit 300a is composed of the first metal layer 310 and the second layer 320, but the inventive concept is not limited thereto. The contact unit 300a of the shielding structure 300 may further include a third metal layer covering the bottom surface of the first metal layer 310. The third metal layer may include a material for shielding radiation. By way of an example, the third metal layer may include tungsten (W), lead (Pb), bismuth (Bi), gold (Au), silver (Ag), or the like. The third metal layer may be composed of the same material as that composing the second metal layer 320.

In addition, it is shown in FIG. 4 that the contact unit 300a of the shielding structure 300 includes the first metal layer 310 and the second layer 320, but the inventive concept is not limited thereto. In the entire region of the shield structure 300, the first metal layer 310 and the second metal layer 320 may be included. Specifically, the protruding unit 300b and the connection unit 300c may also include the first metal layer 310 and the second metal layer 320. Alternatively, as necessary, in the entire region of the shield structure 300, the first metal layer 310, the second metal layer 320, and the third metal layer may be included.

As the shielding structure 300 includes a material for shielding radiation, the shielding structure 300 may protect the semiconductor chip 200 from radiation transferred externally. More specifically, the shielding structure 300 may reduce a region in which the gate insulation layer of the semiconductor chip 200 vulnerable to radiation is exposed to radiation. Accordingly, a semiconductor package with improved structural stability may be provided.

Furthermore, as the shielding structure 300 is composed of a conductive material with a high thermal conductivity, heat generated in the semiconductor chip 200 may be rapidly discharged upward of the semiconductor package through the shielding structure 300. More specifically, as the shielding structure 300 covers a portion of the top surface of the semiconductor chip 200, the heat generated in the semiconductor chip 200 may be transferred to the outside along the shielding structure 300. Accordingly, a semiconductor package with improved heat dissipation characteristics may be provided.

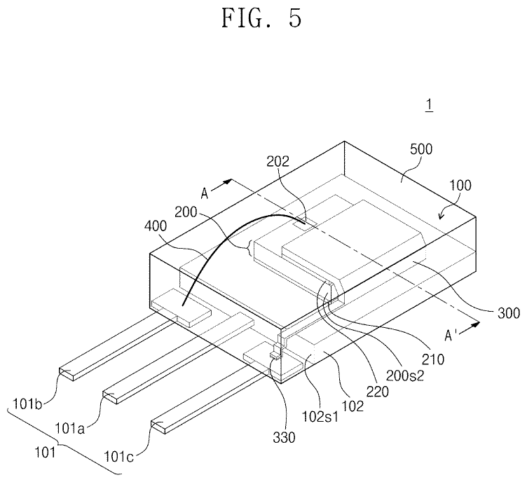

FIG. 5 is a perspective view for explaining a semiconductor package according to an embodiment of the inventive concept. Referring to FIG. 5, the semiconductor package 1 (see FIG. 1) may further include a molding layer 500 covering the semiconductor chip 20, the wire 400, and the shielding structure 300 on the top surface of the lead frame 100. The molding layer 500 may surround the semiconductor chip 200, the wire 400, and the shielding structure 400 on the mounting surface of the pad 102. The molding layer 500 may protrude from the mounting surface in a direction to which the leads 101 extend. The molding layer 500 may cover a portion of the top surface of the leads 101 and fill a portion of a space between the leads 101. In other words, the molding layer 500 may cover a partial area of the leads 101 adjacent to the first side 102s1 of the pad 102. By way of an example, one end of the second lead 101b connected to the wire 400 and one end of the third lead 101c connected to the shielding structure 300 may be covered with the molding layer 500. Among the leads 101, portions that are not covered with the molding layer 500 may be utilized as outer leads that electrically connect the semiconductor package 1 to an external electric device such as a printed circuit board (PCB), a main board, or a module substrate. The molding layer 500 may include an insulating polymer material. For example, the molding layer 500 may include an epoxy molding compound (EMC).

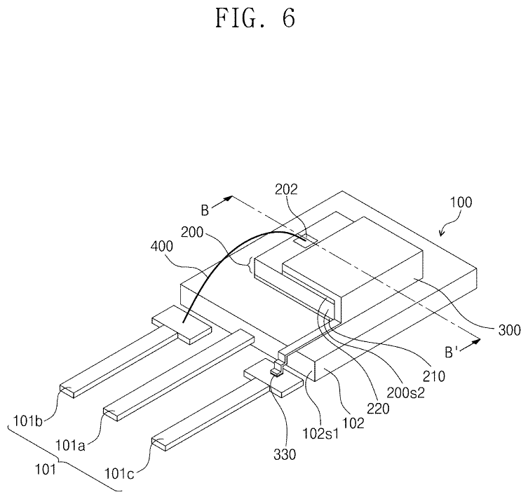

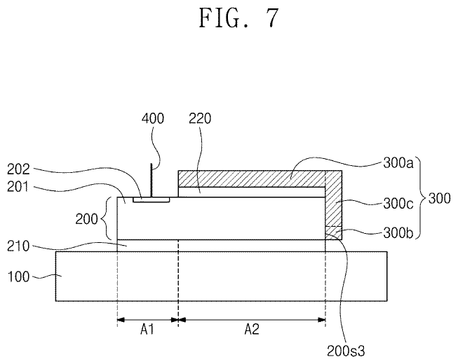

In FIG. 2, it is shown that the contact unit 300c of the shielding structure 300 is spaced apart from the third side 200s3 of the semiconductor chip 200, but the inventive concept is not limited thereto. FIG. 6 is a perspective view for explaining a semiconductor package according to an embodiment of the inventive concept. FIG. 7 is a cross-sectional view cut along line B-B′ of FIG. 6 in order to explain a semiconductor package according to an embodiment of the inventive concept. Referring to FIGS. 6 and 7, a semiconductor chip 200 and a shielding structure 300 may be provided on a lead frame 100. The lead frame 100, the semiconductor chip 200, and the shielding structure 300 may be substantially the same as those described with reference to FIGS. 1 to 4. By way of an example, on the second area A2, the contact unit 300a may cover the top surface of the semiconductor chip 200. The contact unit 300a may vertically overlap the second area A2 of the semiconductor chip 200. However, unlike FIG. 1, the shielding structure 300 may contact the third side 200s3 of the semiconductor chip 200. The connection unit 300c may extend in a direction vertical to the top surface of the contact unit 300a. By way of an example, an angle formed by the inner surface of the connection unit 300c and the bottom surface of the contact unit 300a may be about 90°. A portion of the inner surface of the connection unit 300c may contact the third side 200s3 of the semiconductor chip 200.

In a plan view, the connection unit 300c may vertically overlap at least a portion of the protruding unit 300b. The inner surface of the connection unit 300c may be coplanar with the inner surface of the protruding unit 300b. A portion of the inner surface of the protruding unit 300b may contact the third side 200s3 of the semiconductor chip 200. In other words, the cross section obtained by cutting the shielding structure 300 along line B-B′ may have the shape of ‘┐’. The protruding unit 300b may extend toward a direction to which the third lead 101c extends from the connection unit 300c.

As the shielding structure 300 covers the top surface of the semiconductor chip 200 and at least a portion of the third side 200s3, the semiconductor chip 200 may be more effectively protected from radiation transferred from the outside. Namely, the shielding structure 300 may reduce an area in which the semiconductor chip 300 is exposed to the radiation. Accordingly, a semiconductor package with improved structural stability may be provided.

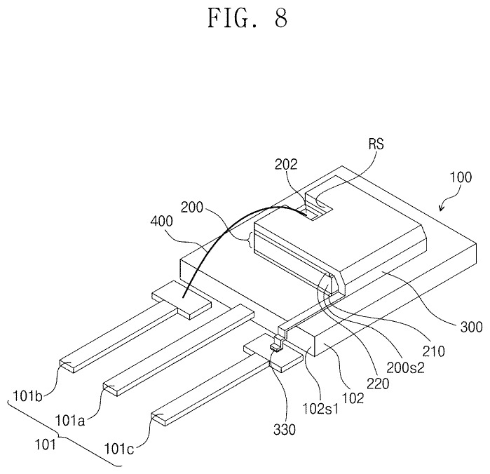

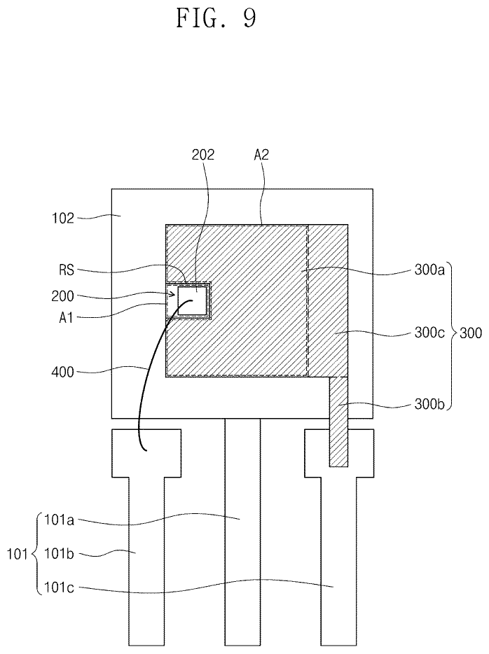

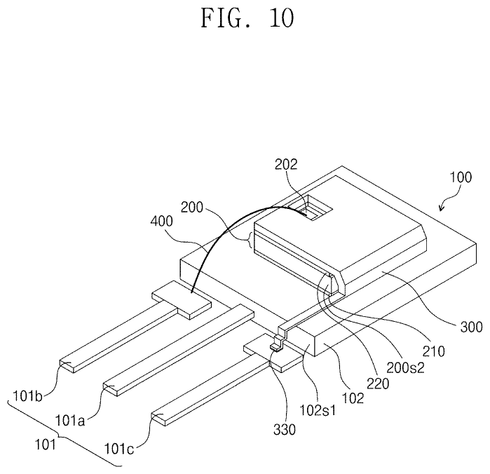

FIG. 8 is a perspective view for explaining a semiconductor package according to an embodiment of the inventive concept. FIG. 9 is a plan view for explaining a semiconductor package according to an embodiment of the inventive concept, and shows the semiconductor package of FIG. 8. Referring to FIGS. 8 and 9, a semiconductor chip 200 and a shielding structure 300 may be provided on a lead frame 100. The lead frame 100, the semiconductor chip 200, and the shielding structure 300 may be substantially the same as those described with reference to FIGS. 1 to 4. However, unlike FIG. 1, the shielding structure 300 may surround three sides among the sides of the gate terminal 202 of the semiconductor chip 200. The planar shape of the contact unit 300a of the shielding structure 300 may be the shape of ‘⊏’.

In other words, the contact unit 300a may include a recess area RS. The recess area RS may mean an area recessed toward the inside of the contact unit 300a from one side of the contact unit 300a. The one side of the contact unit 300a may mean a side facing a side which contacts the connection unit 300c, among the sides of the contact unit 300a. Inner surfaces of the recess area RS may surround three sides of the gate terminal 202. The inner surfaces of the recess area RS may be spaced apart from the three sides of the gate terminal 202. The recess area RS may expose the top surface of the gate terminal 202 to the top surface of the contact unit 300a of the shielding structure 300.

In other words, the first area A1 of the top surface of the semiconductor chip 200 may mean a partial area, which is exposed to the recess area RS of the contact unit 300a, of the top surface of the semiconductor chip 200. The second area A2 of the top surface of the semiconductor chip 200 may mean the remaining area except for the partial area of the top surface of the semiconductor chip 200. The shielding structure 300 may cover the second area A2 of the semiconductor chip 200 and expose the first area A1. As the contact unit 300a of the shielding structure 300 surrounds the three sides of the gate terminal 202, an area of the semiconductor chip 200 protected by the shielding structure 300 may increase.

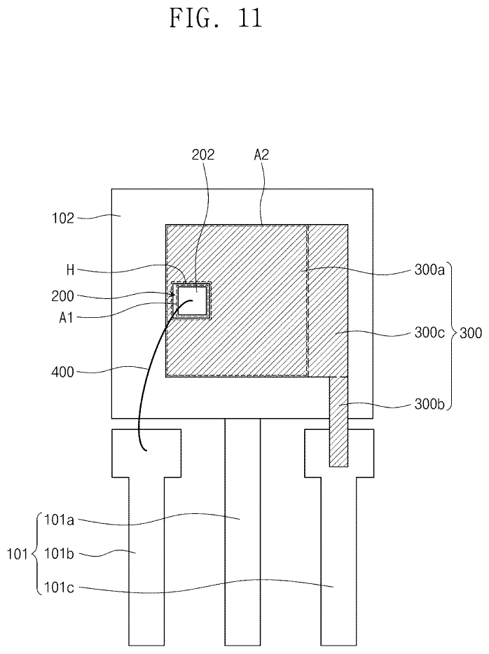

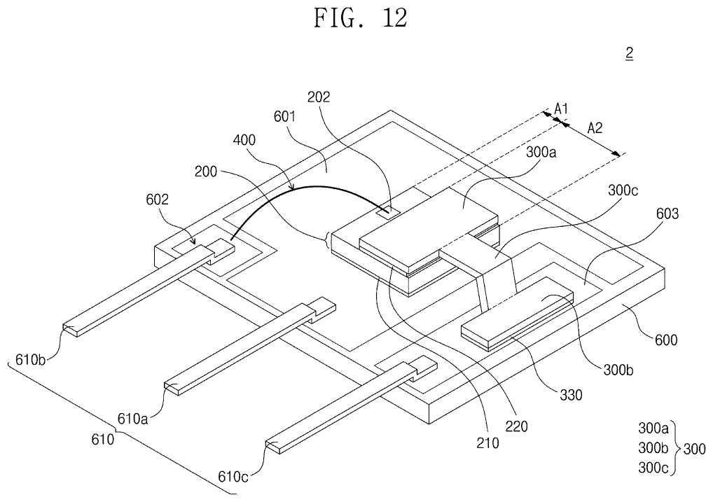

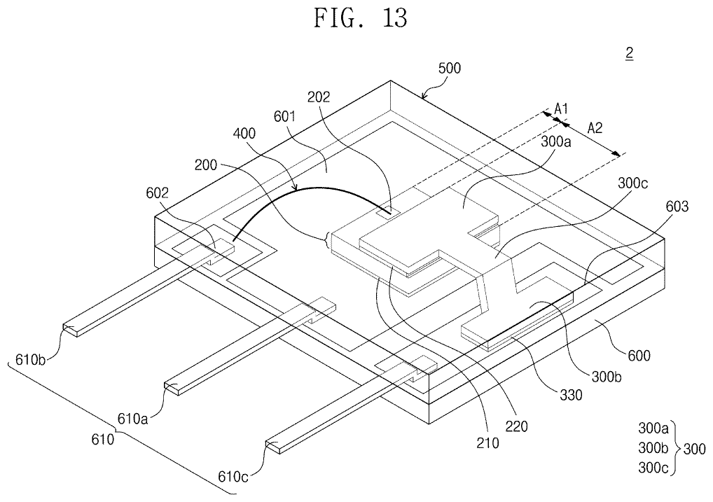

FIG. 10 is a perspective view for explaining a semiconductor package according to an embodiment of the inventive concept. FIG. 11 is a plan view for explaining a semiconductor package according to an embodiment of the inventive concept, and shows the semiconductor package of FIG. 10. Referring to FIGS. 10 and 11, a semiconductor chip 200 and a shielding structure 300 may be provided on a lead frame 100. The lead frame 100, the semiconductor chip 200, and the shielding structure 300 may be substantially the same as those described with reference to FIGS. 1 to 4. However, unlike FIG. 1, the shielding structure 300 may surround four sides of the gate terminal 202 of the semiconductor chip 200.

The contact unit 300a may include a hole H. The hole H may penetrate through the contact unit 300a in a direction vertical to the top surface of the lead frame 100. The hole H may have the same planar shape as the gate terminal 202, but the inventive concept is not limited thereto. The planar shape of the hole H may be rectangular, polygonal, or circular. The planar area of the hole H may be larger than that of the gate terminal 202. In a plan view, the gate terminal 202 may be disposed inside the hole H. The contact unit 300a of the shielding structure 300 may surround the sides of the gate terminals 202. The contact unit 300a of the shielding structure 300 may be spaced apart from the sides of the gate terminal 202. The top surface of the gate terminal 202 may be exposed to the top surface of the contact unit 300a of the shielding structure 300 through the hole H.

In other words, the first area A1 of the top surface of the semiconductor chip 200 may mean a partial area, which is exposed to the hole H of the contact unit 300a, of the top surface of the semiconductor chip 200. The second area A2 of the top surface of the semiconductor chip 200 may mean the remaining area except for the partial area of the top surface of the semiconductor chip 200. The shielding structure 300 may cover the second area A2 of the semiconductor chip 200 and expose the first area A1. As the contact unit 300a of the shielding structure 300 surrounds all the four sides of the gate terminal 202, an area of the semiconductor chip 200 protected by the shielding structure 300 may increase.

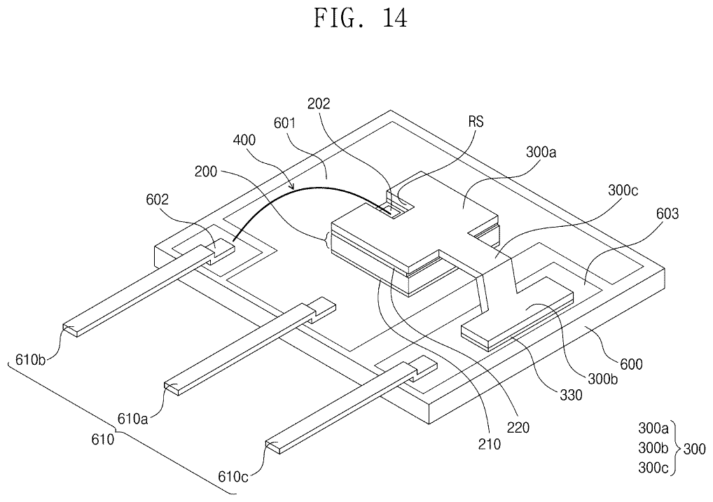

FIG. 12 is a perspective view for explaining a semiconductor package according to an embodiment of the inventive concept. Referring to FIG. 12, a semiconductor package 2 may include a substrate 600, leads 610 on the substrate 600, a semiconductor chip 200, and a shielding structure 300. The semiconductor chip 200 and the shielding structure 300 may be substantially similar to those described with reference to FIG. 1.

The substrate 600 may include a core unit (not shown) and a substrate wiring layer (not shown) disposed on the core unit. The core unit may include an insulation material. By way of an example, the core unit may include a ceramic material. The substrate wiring layer may be provided on the top surface of the core unit. The substrate wiring layer may include at least one insulation pattern and a wiring pattern inside the insulation pattern. In the specification, the substrate wiring layer may mean a wiring layer provided by patterning each of one insulation material layer and one conductive material layer. Namely, the wiring patterns inside the one substrate wiring layer may horizontally extend and not vertically overlap.

The insulation pattern may include an inorganic insulation layer such as a silicon oxide (SiOₓ) or a silicon nitride (SiNₓ). Alternatively, the insulation pattern may include a polymer material. The insulation pattern may include an insulating polymer or a photoimageable dielectric (PID) polymer. For example, the PID polymer may include at least one of polyimide, polybenzoxazole (PBO), phenol-based polymer, or a benzocyclobutene-based polymer. The wiring pattern may be provided on the top surface of the insulation pattern. The wiring pattern may protrude from the top surface of the insulation pattern. The wiring pattern may horizontally extend on the top surface of the insulation pattern. The wiring pattern may be a pad portion or a wiring portion of the substrate wiring layer. The wiring pattern may include a conductive material. For example, the wiring pattern may include copper (Cu).

A first substrate pad 601, a second substrate pad 602, and a third substrate pad 603 may be provided on the top surface of the substrate 600. The first to third substrate pads 601, 602, and 603 may be portions of the wiring pattern exposed from the substrate wiring layer to the top surface of the substrate 600. The first substrate pad 601, the second substrate pad 602, and the third substrate pad 603 may be horizontally spaced apart on the top surface of the substrate 600.

Substrate leads 610 may be provided on the top surface of the substrate 600. Similarly to the leads 101 (see FIG. 1) described with reference to FIG. 1, the substrate leads 610 may serve to transfer electrical signals outside the package. The substrate leads 610 may be electrically connected to the substrate 600. One end of each of the substrate leads 610 may contact the top surface of the substrate 600. Each of the substrate leads 610 may have a linear shape extending in one direction that is parallel to the top surface of the substrate 600. The substrate leads 610 may extend in the one direction to protrude from one side of the substrate 600. As necessary, the substrate leads 610 may have at least one step. Each of the substrate leads 610 may be horizontally spaced apart on the top surface of the substrate 600. The substrate leads 610 may include a conductive material. By way of an example, the substrate leads 610 may be composed of a metal with a relatively excellent electrical conductivity such as copper (Cu), iron-nickel (Fe—Ni), aluminum (Al), or stainless steel, or an alloy thereof.

The substrate leads 610 may be electrically connected to the first to third substrate pads 601, 602, and 603, respectively. By way of an example, the substrate leads 610 may be respectively provided on the top surfaces of the first substrate pad 601, the second substrate pad 602, and the third substrate pad 603. Hereinafter, for convenience of description, a substrate lead provided on the top surface of the first substrate pad 601 will be referred to as a first substrate lead 610a, a substrate lead provided on the top surface of the second substrate pad 602 will be referred to as a second substrate lead 610b, and a substrate lead provided on the top surface of the third substrate pad 603 will be referred to as a third substrate lead 610c. Here, the first substrate lead 610a may be a lead through which a current input or output from the drain electrode of the semiconductor chip 200 is transferred outside. The second substrate lead 610b may be a lead through which a current input or output from the gate electrode of the semiconductor chip 200 is transferred outside. The third substrate lead 610c may be a lead a current input or output from the source electrode of the semiconductor chip 200 is transferred outside.

The semiconductor chip 200 may be disposed on the first substrate pad 601 of the substrate 600. On the first substrate pad 601, the semiconductor chip 200 may be horizontally spaced apart from the first substrate lead 610a. The semiconductor chip 200 may be attached onto the first substrate pad 601 through the first adhesive layer 210 that is provided on the bottom surface of the semiconductor chip 200. The drain terminal (not shown) exposed to the bottom surface of the semiconductor chip 200 may be electrically connected to the first substrate lead 610a through the first adhesive layer 210.

The top surface of the semiconductor chip 200 may include a first area A1 and a second area A2. The first area A1 and the second area A2 may be substantially the same as those described with reference to FIGS. 1 to 3. The first area A1 of the semiconductor chip 200 may include an area in which the gate terminal 202 protrudes from the top surface of the semiconductor chip 200. A whole portion, which includes the area in which the gate terminal 202 protrudes, of the top surface of the semiconductor chip protrudes may be defined as the first area A1. The second area A2 may include an area in which the source terminal protrudes from the top surface of the semiconductor chip 200. The second area A2 may mean the remaining area, which excludes the first area A1, of the top surface of the semiconductor chip 200.

A wire 400 electrically connecting the semiconductor chip 200 and the second substrate pad 602 may be provided. The wire 400 may extend from the gate terminal 202 of the semiconductor chip 200 to be connected to the second substrate pad 602. A current input or output from a gate area of the semiconductor chip 200 may be transferred outside through the gate terminal 202, the wire 400, the second substrate pad 602, and the second substrate lead 610b.

The shielding structure 300 may be provided on the top surface of the semiconductor chip 200. The contact unit 300a of the shielding structure 300 may cover at least a portion of the top surface of the semiconductor chip 200. The contact unit 300a of the shielding structure 300 may cover the second area A2 of the semiconductor chip 200. The bottom surface of the protruding unit 300b may be connected to the top surface of the substrate 600. The protruding unit 300b of the shielding structure 300 may be connected to the third substrate pad 603. The protruding unit 300b may be horizontally spaced apart from the third substrate lead 610c on the third substrate pad 603. The shielding structure 300 may electrically connect the source terminal to the third substrate lead 610c through the substrate 600. The connection unit 300c may connect the contact unit 300a and the protruding unit 300b. As necessary, the connection unit 300c may have at least one bending unit.

The protruding unit 300b may be attached to the third substrate pad 603 through a third adhesive layer 330 that is provided on the bottom surface of the protruding unit 300b. A current input or output from the source terminal of the semiconductor chip 200 may be transferred outside through the shielding structure 300, the third substrate pad 603, and the third substrate lead 610c.

FIG. 13 is a perspective view for explaining a semiconductor package according to an embodiment of the inventive concept. Referring to FIG. 13, the semiconductor package 2 (see FIG. 12) may further include a molding layer 500 covering the semiconductor chip 200, the wire 400, and the shielding structure 300 on the top surface of the lead frame 600. The molding layer 500 may cover a partial area of the substrate leads 610 which vertically overlap the first to third substrate pads 601, 602, and 603. Among the substrate leads 610, portions that are not covered by the molding layer 500 and protrude in an outer direction of one side of the molding layer 500 may be utilized as outer leads that electrically connect the semiconductor package 2 to an external electrical device such as a printed circuit board PCB, a main board, or a module substrate. The molding layer 500 may include an insulating polymer material. For example, the molding layer 500 may include an epoxy molding compound (EMC).

FIG. 14 is a perspective view for explaining a semiconductor package according to an embodiment of the inventive concept. Referring to FIG. 14, a semiconductor chip 200 and a shielding structure 300 may be provided on a substrate 600. The substrate 600, the semiconductor chip 200 and the shielding structure 300 may be substantially the same as those described with reference to FIG. 12. However, unlike FIG. 12, the shielding structure 300 may surround three sides among the sides of the gate terminal 202 of the semiconductor chip 200. The planar shape of the contact unit 300a may be substantially similar to that of the contact unit 300a (see FIG. 8) described with reference to FIG. 8. By way of an example, the planar shape of the contact unit 300a may be the shape of ‘⊏’.

The contact unit 300a may include a recess area RS. The recess area RS may mean an area recessed toward the inside of the contact unit 300a from one side of the contact unit 300a. The one side of the contact unit 300a may mean a side facing a side which is adjacent to the connection unit 300c, among the sides of the contact unit 300a. Inner surfaces of the recess area RS may surround the sides of the gate terminal 202. The inner surfaces of the recess area RS may be spaced apart from the sides of the gate terminal 202. The recess area RS may expose the top surface of the gate terminal 202 to the top surface of the contact unit 300a of the shielding structure 300.

Here, although not shown, the first area A1 of the top surface of the semiconductor chip 200 may mean a partial area, which is exposed to the recess area RS of the contact unit 300a, of the top surface of the semiconductor chip 200. The second area A2 of the top surface of the semiconductor chip 200 may mean the remaining area except for the partial area of the top surface of the semiconductor chip 200. The shielding structure 300 may cover the second area A2 of the semiconductor chip 200 and expose the first area A1.

In FIG. 14, it is shown that the contact unit 300a includes the recess area RS, but the inventive concept is not limited thereto. Similarly to the described above with reference to FIG. 10, the contact unit 300a may include the hole H (see FIG. 10) and surround four sides of the gate terminal 202.

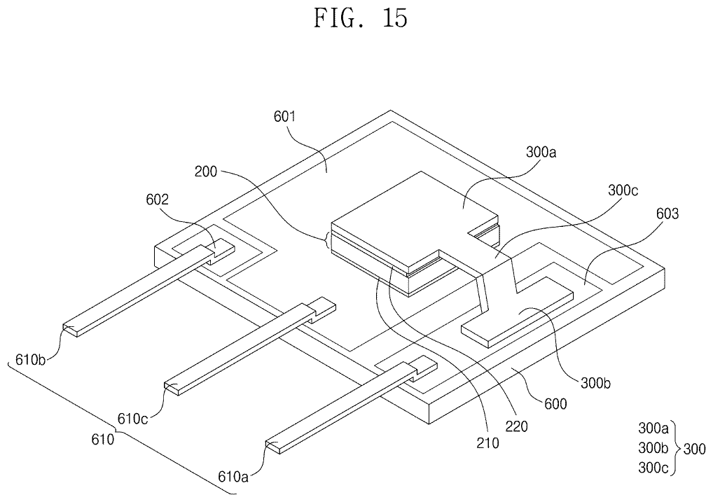

FIG. 15 is a perspective view for explaining a semiconductor package according to an embodiment of the inventive concept. Referring to FIG. 15, a semiconductor chip 200 and a shielding structure 300 may be provided on a substrate 600. The substrate 600 and the semiconductor chip 200 may be substantially the same as those described with reference to FIG. 12. However, unlike FIG. 12, the semiconductor chip 200 may be mounted on the substrate 600 in a face-down manner. The semiconductor chip 200 may be mounted in a flip-chip manner. The gate terminal 202 (see FIG. 12) and the source terminal (not shown) of the semiconductor chip 200 may be disposed on the bottom surface of the semiconductor chip 200. The drain terminal (not shown) may be disposed on the top surface of the semiconductor chip 200.

The disposition and planar shapes of the first to third substrate pads 601, 602, and 603 may vary as necessary. The substrate leads 610 may be disposed on the first to third substrate pads 601, 602, and 603. Each of the first to third substrate leads 601a, 601b, and 601c may be properly disposed on the first to third substrate pads 601, 602, 603 so that each of the drain terminal, the gate terminal 202, and the source terminal of the semiconductor chip 200 may be electrically connected to the outside. The gate terminal 202 and the source terminal may be electrically connected to the respective corresponding leads 610 through the substrate wiring layer of the substrate 600. As the gate terminal 202 is electrically connected to the second substrate lead 610b through the substrate 600, the wire 400 (see FIG. 12) connecting the gate terminal 202 and the second substrate lead 610b may not be provided.

The shielding structure 300 may be provided on the top surface of the semiconductor chip 200. The shielding structure 300 may cover the entire top surface of the semiconductor chip 200. The contact unit 300a of the shielding structure 300 may vertically overlap the semiconductor chip 200. The top surface of the semiconductor chip 200 may not be exposed to the shielding structure 300. Some sides of the contact unit 300a may be aligned with the sides of the semiconductor chip 200. The some sides of the contact unit 300a may mean sides except for sides connected to the connection unit 300c among the sides of the contact unit 300a. However, the inventive concept is not limited thereto, and the contact unit 300a may protrude from the sides of the semiconductor ship 200. By way of an example, the planar area of the contact unit 300a may be larger than that of the semiconductor chip 200. Although not shown, the molding layer 500 (see FIG. 13) covering the semiconductor chip 200 and the shielding structure 300 may be further included on the top surface of the substrate 600 as necessary.

The shielding structure 300 may electrically connect the drain terminal to the first substrate lead 610a. The shielding structure 300 may prevent radiation transferred from the outside from being incident onto the top surface of the semiconductor chip 200. As the contact unit 300a of the shielding structure 300 covers the entire top surface of the semiconductor chip 200, an area of the semiconductor chip 200 protected by the shielding structure 300 may increase. A semiconductor package with increased radiation shielding effects may be provided.

The semiconductor package according to the embodiments of the inventive concept may include a clip-type radiation shielding structure covering a portion of a semiconductor element to protect the semiconductor element from radiation.

In the semiconductor package according to the embodiments of the inventive concept, a radiation shielding structure composed of a material with a high thermal conductivity covers a portion of a semiconductor element, so that the semiconductor element with improved heat dissipation characteristics may be provided.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A semiconductor package comprising:
a semiconductor chip;
a lead frame provided on a bottom surface of the semiconductor chip and extending beyond a first side of the semiconductor chip;
a wire extending from a first area of a top surface of the semiconductor chip, wherein the wire is connected to the lead frame from the first side of the semiconductor chip; and
a shielding structure covering a second area of the top surface of the semiconductor chip and exposing the first area,
wherein the shielding structure comprises:
a contact unit covering the second area of the top surface of the semiconductor chip;
a protruding unit connected to the lead frame from a second side of the semiconductor chip; and
a connection unit connecting the contact unit and the protruding unit,
wherein the shielding structure comprises tungsten (W).

2. The semiconductor package of claim 1, wherein:
the first area and the second area of the top surface of the semiconductor chip are horizontally spaced apart from each other,
the semiconductor ship comprises a gate terminal provided on the first area and a source terminal provided on the second area,
the gate terminal is exposed to the top surface of the semiconductor chip, and
the wire extends from the gate terminal to contact the lead frame.

3. The semiconductor package of claim 2,
wherein the semiconductor chip further comprises a drain terminal exposed to the bottom surface of the semiconductor chip,
wherein the drain terminal is electrically connected to the lead frame by a first adhesive layer provided on the bottom surface of the semiconductor chip.

4. The semiconductor package of claim 2, wherein:
the lead frame comprises a pad and a plurality of leads extending from one side of the pad in one direction parallel to a top surface of the pad,
the semiconductor chip is disposed on the top surface of the pad,
the wire electrically connects the gate terminal and any one of the leads, and
the protruding unit electrically connects the source terminal and another one of the leads.

5. The semiconductor package of claim 4, wherein:
a level of a bottom surface of the protruding unit is lower than that of a bottom surface of the contact unit,
the protruding unit extends in the one direction to be connected to the other lead, and
the connection unit is bent from a top surface of the contact unit.

6. The semiconductor package of claim 1, wherein:
the semiconductor chip comprises a gate terminal provided on the first area,
the gate terminal is exposed to the top surface of the semiconductor chip, and
the second area corresponds to a remaining area of the top surface of the semiconductor chip except for the area in which the gate terminal is exposed.

7. The semiconductor package of claim 1, further comprising a molding layer covering the semiconductor chip and the shielding structure on the lead frame,
wherein the molding layer comprises an epoxy-based polymer.

8. The semiconductor package of claim 1, further comprising a second adhesive layer intervened between the top surface of the semiconductor chip and a bottom surface of the contact unit,
wherein the second adhesive layer comprises a conductive material.

9. The semiconductor package of claim 1, wherein:
a bottom surface of the contact unit and an inner surface of the connection unit form an obtuse angle, and
the inner surface of the connection unit is spaced apart from the second side of the semiconductor chip.

10. The semiconductor package of claim 1, wherein:
the connection unit of the shielding structure extends in a direction vertical to a top surface of the contact unit, and
the connection unit contacts the second side of the semiconductor chip.

11. The semiconductor package of claim 1,
wherein the contact unit of the shielding structure comprises a first metal layer and second metal layer laminated in order,
wherein the first metal layer comprises copper (Cu), and
the second metal layer comprises tungsten (W).

12. A semiconductor package comprising:
a semiconductor chip, wherein the semiconductor chip comprises a gate terminal protruding from a top surface of the semiconductor chip;
a lead frame provided on a bottom surface of the semiconductor chip and extending to one side of the semiconductor chip; and
a shielding structure covering at least a portion of the top surface of the semiconductor chip,
wherein the shielding structure comprises:
a contact unit covering at least a portion of the top surface of the semiconductor chip;
a protruding unit connected to the lead frame; and
a connection unit connecting the contact unit and the protruding unit, and bent from the contact unit,
wherein the contact unit surrounds at least three of sides of the gate terminal.

13. The semiconductor package of claim 12, wherein:
the contact unit comprises a first hole penetrating through the contact unit, and
the gate terminal is exposed to a top surface of the shielding structure by the first hole.

14. The semiconductor package of claim 12, further comprising a molding layer surrounding the semiconductor chip and the shielding structure on the lead frame,
wherein the molding layer comprises an epoxy-based polymer.

15. The semiconductor package of claim 12,
wherein the contact unit comprises a first metal layer and second metal layer laminated in order,
wherein the first metal layer comprises copper (Cu), and
the second metal layer comprises tungsten (W).

16. The semiconductor package of claim 15,
wherein the contact unit further comprises a third metal layer covering a bottom surface of the first metal layer,
wherein the third metal layer comprises tungsten (W).

17. A semiconductor package comprising:
a substrate comprising a wiring layer;
a semiconductor chip disposed on a top surface of the substrate;
a first lead and a second lead spaced apart from the semiconductor chip on the top surface of the substrate; and
a shielding structure covering an entire top surface of the semiconductor chip, wherein
each of the first lead and the second lead extends to one side of the substrate in one direction parallel to the top surface of the substrate,
the shielding structure comprises a first bottom surface and a second bottom surface positioned at different vertical levels, wherein
the first bottom surface covers the top surface of the semiconductor chip, and
the second bottom surface is connected to the top surface of the semiconductor chip,
the semiconductor chip comprises a semiconductor substrate and a drain terminal provided on a top surface of the semiconductor substrate, and
the shielding structure electrically connects the drain terminal and the first lead.

18. The semiconductor package of claim 17, wherein:
the semiconductor chip further comprises a gate terminal provided on a bottom surface of the semiconductor substrate, and
the wiring layer electrically connects the gate terminal and the second lead.

19. The semiconductor package of claim 17,
wherein the shielding structure comprises a first metal layer and a second metal layer laminated on the first metal layer,
wherein the second metal layer comprises tungsten (W).

20. The semiconductor package of claim 17,
wherein the substrate further comprises a core layer provided on a bottom surface of the wiring layer,
wherein the core layer comprises ceramic.
